(19) United States
(12) Patent Application Publication
(10) Pub. No.: US 2023/0403930 A1
(43) Pub. Date: Dec. 14, 2023

(54) LIGHT EMITTING ELEMENT, DISPLAY DEVICE, LIGHTING DEVICE, AND METHOD FOR PRODUCING LIGHT EMITTING ELEMENT

(71) Applicant: SHARP KABUSHIKI KAISHA, Sakai City, Osaka (JP)

(72) Inventors: YUSUKE SAKAKIBARA, Sakai City, Osaka (JP); Yuma YAGUCHI, Sakai City, Osaka (JP)

(21) Appl. No.: 18/033,753

(22) PCT Filed: Oct. 30, 2020
(86) PCT No.: PCT/JP2020/040913

§ 371 Date: Apr. 25, 2023

(51) Int. Cl. H10K 85/60; C09K 11/06

(52) U.S. Cl. CPC H10K 85/60; C09K 11/06; H10K 50/16

(57) ABSTRACT

A light-emitting element according to the disclosure includes, in the recited order, an anode, a blue light-emitting layer, an electron transport layer and a cathode, wherein the electron transport layer includes a nanoparticle containing a metal oxide, and a ligand containing a thiol group.

### TECHNICAL FIELD

The present invention relates to a light-emitting element, to a display device and a lighting device that include the light-emitting element, and to a method for producing the light-emitting element.

### BACKGROUND ART

Conventional nanoparticles have been stabilized by adding ligands to the nanoparticles.

Patent Literatures 1 to 3 describe various ligands including a ligand that can be coordinated to a nanoparticle by a thiol group. Non-Patent Literature 1 describes ethanolamine as the ligands of ZnO nanoparticles, and Non-Patent Literature 2 describes oleic acid as the ligands of ZnO nanoparticles.

### CITATION LIST

### Patent Literatures

Patent Literature 1: US 2004/0101976A1
Patent Literature 2: US 2018/0346810A1
Patent Literature 3: US 2019/0198796A1

### Non-Patent Literature

Non-Patent Literature 1: Nature, 515, 96-99 (2014), Solution-processed, high-performance light-emitting diodes based on quantum dots
Non-Patent Literature 2: ACS Appl. Mater. Interfaces 2010, 2, 6, 1769-1773, Sol-Gel Growth of Hexagonal Faceted ZnO Prism Quantum Dots with Polar Surfaces for Enhanced Photocatalytic Activity

### SUMMARY OF INVENTION

### Technical Problem

Using ethanolamine or oleic acid as ligands, as described in Non-Patent Literatures 1 and 2, cannot sufficiently avoid a time-course increase in the particle diameters of ZnO nanoparticles, that is, a time-course decrease in the band gaps of the ZnO nanoparticles within a thin film. This problem is seen conspicuously as the particle diameters of the ZnO nanoparticles are small.

Patent Literatures 1 to 3 fail to disclose or suggest at all whether which of the ligands can sufficiently avoid a time-course change in the particle diameters and band gaps of the ZnO nanoparticles within the thin film.

As such, it is difficult for the conventional techniques to avoid time-course aggregation and growth of the nanoparticles within the thin film.

### Solution to Problem

To solve the above problem, a light-emitting element according to one aspect of the present disclosure includes the following: an anode; a cathode; a light-emitting layer disposed between the anode and the cathode; and an electron transport layer disposed between the anode and the light-emitting layer, wherein the electron transport layer includes a nanoparticle containing a metal oxide, and a ligand containing a thiol group.

To solve the above problem, a method for producing a light-emitting element according to one aspect of the present disclosure includes the following: a reaction step of causing a metal-oxide precursor to react with a hydroxide ion within a first solution to generate a nanoparticle including a metal oxide; a first addition step of generating, after the reaction step, a quantum dot including the nanoparticle and a ligand within a second solution in which a first alcohol and the ligand containing a thiol group are added to the nanoparticle; and an application step of applying a third solution containing the quantum dot onto a substrate after the first addition step.

### Advantageous Effect of Invention

These aspects of the present disclosure can highly avoid time-course aggregation and growth of nanoparticles within a thin film.

### BRIEF DESCRIPTION OF DRAWINGS

FIG. 1 is a flowchart showing an example method for producing a display device according to one embodiment of the present invention.

FIG. 2 is a schematic sectional view of an example configuration of the display region of the display device according to one embodiment of the present invention.

FIG. 3 is a schematic sectional view of an example configuration of a light-emitting element layer in the display device according to one embodiment of the present invention.

FIG. 4 is a flowchart showing an example method for producing a light-emitting element illustrated in FIG. 3.

FIG. 5 illustrates, in sectional view, the example method for producing the light-emitting element illustrated in FIG. 3.

FIG. 6 illustrates, in sectional view, the example method for producing the light-emitting element illustrated in FIG. 3.

FIG. 7 illustrates, in sectional view, the example method for producing the light-emitting element illustrated in FIG. 3.

FIG. 8 is a flowchart showing an example process step of preparing a material solution for an electron transport layer shown in FIG. 4.

FIG. 9 schematically illustrates the example process step of preparing the material solution for the electron transport layer shown in FIG. 4.

FIG. 10 is a graph showing the boiling point and melting point of straight-chain alkane (CₙH₂ₙ₊₂).

FIG. 11 is a graph showing the boiling point and melting point of annular cycloalkane (CₙH₂ₙ).

FIG. 12 is a schematic diagram of the energy level of a light-emitting element according to Example 1.

FIG. 13 is a schematic diagram of the energy level of a light-emitting element according to Comparative Example 1.

FIG. 14 is a graph showing band gap measurements of a nanoparticle for each of the light-emitting elements according to Examples 1 and 2 and according to Comparative Examples 1 to 3.

### DESCRIPTION OF EMBODIMENTS

### First Embodiment

Method for Producing Display Device and Configuration of Display Device

The term “in the same layer” hereinafter means that one layer is formed in the same process step (film formation step) as another layer, the term “under” hereinafter means that one layer is formed in a process step anterior to a process step of forming a comparative layer, and the term “over” hereinafter means that one layer is formed in a process step posterior to a process step of forming a comparative layer.

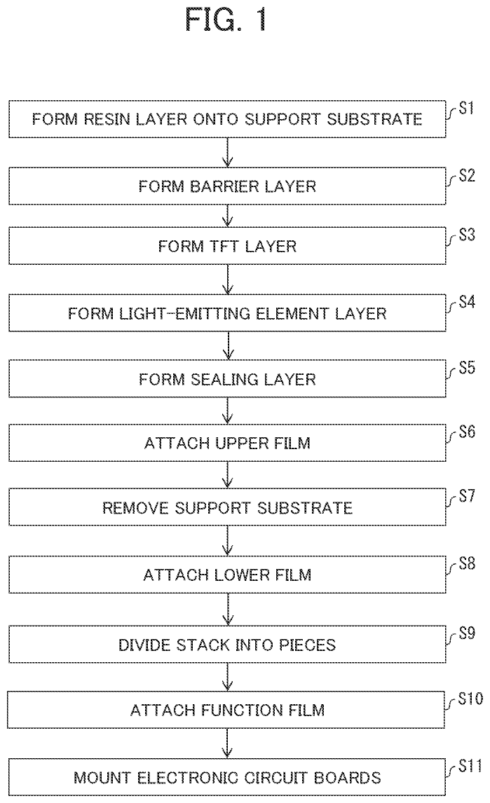

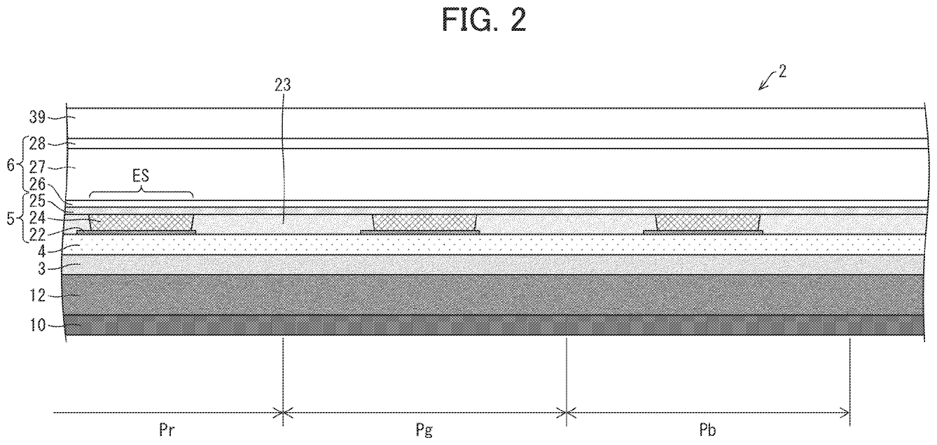

FIG. 1 is a flowchart showing an example method for producing a display device. FIG. 2 is a schematic sectional view of an example configuration of the display region of a display device 2.

For producing the display device 2, which is flexible, the first process step (Step S1) is forming a resin layer 12 onto a light-transparent support substrate (e.g., a mother glass), as illustrated in FIG. 1 and FIG. 2. The next (Step S2) is forming a barrier layer 3. The next (Step S3) is forming a thin-film transistor layer 4 (TFT layer). The next (Step S4) is forming a top-emission light-emitting element layer 5. The next (Step S5) is forming a sealing layer 6. The next (Step S6) is attaching an upper film onto the sealing layer 6.

The next (Step S7) is removing the support substrate from the resin layer 12 through laser light irradiation or other methods. The next (Step S8) is attaching a lower film 10 (substrate) onto the lower surface of the resin layer 12. The next (Step S9) is dividing a stack of the lower film 10, resin layer 12, barrier layer 3, thin-film transistor layer 4, light-emitting element layer 5 and sealing layer 6 into a plurality of pieces. The next (Step S10) is attaching a function film 39 onto the obtained pieces. The next (Step S11) is mounting electronic circuit boards (e.g., an IC chip and an FPC) onto a part (terminal section) of a frame region (a non-display region) surrounding the display region with a plurality of subpixels formed therein. It is noted that Steps S1 through S11 are performed by an apparatus (that includes a film formation apparatus that performs Steps S1 through S5) that produces a display device.

The light-emitting element layer 5 includes the following: an anode 22 (a positive electrode; so-called, a pixel electrode) over a flattening film 21; an insulating edge cover 23 covering the edge of the anode 22; an active layer 24 that is an electroluminescence (EL) layer over the edge cover 23; and a cathode 25 (a negative electrode; so-called, a common electrode) over the active layer 24.

Each subpixel includes the anode 22 in the form of an island, the active layer 24 in the form of an island, and the cathode 25, which constitute a light-emitting element ES (electric-field light-emitting element), i.e., a QLED, in the light-emitting element layer 5; moreover, a subpixel circuit that controls the light-emitting element ES is formed in the thin-film transistor layer 4.

The sealing layer 6 is transparent to light and includes an inorganic sealing film 26 covering the cathode 25, an organic buffer layer 27 over the inorganic sealing film 26, and an inorganic sealing film 28 over the organic buffer layer 27. The sealing layer 6, covering the light-emitting element layer 5, prevents foreign substances, such as water and oxygen, from intrusion into the light-emitting element layer 5.

The foregoing has described a flexible display device; for producing an inflexible display device, forming a resin layer, replacing a base, and other process steps are unnecessary typically; accordingly for instance, the stacking process, i.e., Steps S2 through S5, is performed on a glass substrate, followed by Step S9. Further, for producing an inflexible display device, a light-transparency sealing member may be bonded with a sealing adhesive under a nitrogen atmosphere, instead of or in addition to forming the sealing layer 6. Such a light-transparency sealing member can be made of glass, plastic and other materials and is preferably in the form of a recess.

The first embodiment is directed particularly to the step (Step S4) of forming the light-emitting element layer 5 in the foregoing method for producing the display device. The first embodiment is directed particularly to the active layer 24 among the foregoing components of the display device.

Configuration of Light-Emitting Element

When the display device 2 (display device) performs RGB display, the light-emitting element layer 5 includes, as illustrated in FIG. 2, a red subpixel Pr that emits red light, a green subpixel Pg that emits green light, and a blue subpixel Pb that emits blue light, as well as the light-emitting element ES for each subpixel. It is noted that the scope of the present invention is not limited to a display device; the scope of the present invention also encompasses a lighting device that includes the light-emitting elements ES.

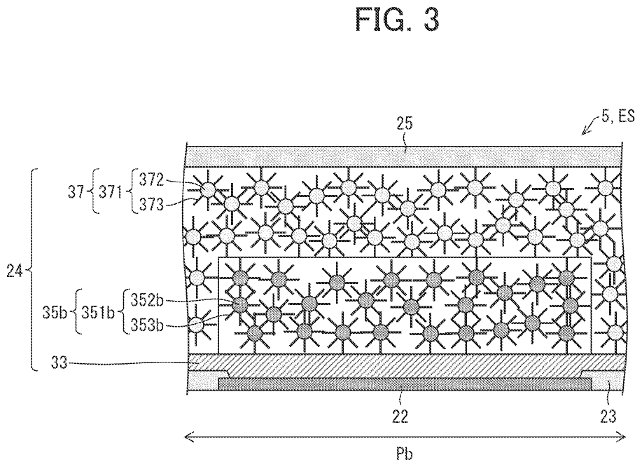

The following details the configuration of the light-emitting element ES according to the first embodiment with reference to FIG. 3.

FIG. 3 is a schematic sectional view of an example configuration of the light-emitting element ES in the blue subpixel Pb according to the first embodiment.

As illustrated in FIG. 3, the light-emitting element layer 5 according to the first embodiment includes the anode 22 (positive electrode), the cathode 25 (negative electrode), and the active layer 24 disposed between the anode 22 and the cathode 25. The active layer 24 in the blue subpixel Pb includes a blue light-emitting layer 35b (light-emitting layer), a hole transport layer 33 disposed between the anode 22 and the blue light-emitting layer 35b, and an electron transport layer 37 disposed between the cathode 25 and the blue light-emitting layer 35b. These components constitute, in the light-emitting element layer 5, the light-emitting element ES that emits blue light. Although not shown, the active layer 24 may include other layers, such as an electron block layer, a hole injection layer, an electron injection layer, a hole block layer and a wavelength conversion layer, freely and selectively. Although the foregoing has described, by way of example, a stack (forward structure) of, in sequence, an anode (reflective electrode), a hole transport layer, a light-emitting layer, an electron transport layer, a cathode (transparent electrode), a stack (reverse structure) of, in sequence, a cathode (reflective electrode), an electron transport layer, a light-emitting layer, a hole transport layer and an anode (transparent electrode) may be provided.

The hole transport layer 33 may be of any configuration; the hole transport layer 33 may include an organic hole-transporting material or an inorganic hole-transporting material.

The blue light-emitting layer 35b emits blue light. The blue light-emitting layer 35b may include an organic light-emitting material or an inorganic light-emitting material. The blue light-emitting layer 35b preferably includes blue quantum dots 351b that emit blue light. The blue quantum dots 351b each include a blue nanoparticle 352b and a ligand 353b that can coordinate with the blue nanoparticle 352b. A “ligand” in the Description is a molecule that is polarized and that can coordinate with a nanoparticle by polarization. A “ligand containing a thiol group” in the Description is in particular a molecule that can be coordinated to a nanoparticle by the thiol group.

The blue nanoparticle 352b may be of any given structure, such as a core type, a core-shell type or a core- multi-shell type. The blue nanoparticle 352b preferably falls under a core-shell type for instance and preferably has such materials and particle diameters as indicted in Table 1 below. Blue light has a wavelength region of about 420 to 495 nm inclusive.

TABLE 1

| Material | Average Particle | VBM | CBM | Light-Emission Central |
|---|---|---|---|---|
| [Core-Shell] | Diameter [nm] | [eV] | [eV] | Wavelength [nm] |
| CdSe-ZnS | 5 | 5.5 | 2.8 | 465 |
| ZnSe-ZnS | 8 | 5.5 | 2.6 | 430 |
| ZnSe-ZnS | 10 | 5.5 | 2.7 | 450 |

The VBM values shown in Table 1 are the differences (i.e., absolute values) in electron energy level between a vacuum and a valence-band upper end (valence band maximum or VBM). The CBMs shown in Table 1 are the differences (i.e., absolute values) in electron energy level between a vacuum and a conduction-band lower end (conduction band minimum or CBM). Hereinafter, the difference in electron energy level between a vacuum and a VBM will be referred to as a VBM value, and the difference in electron energy level between a vacuum and a CBM will be referred to as a CBM value.

Each nanoparticle's VBM value in the Description is a measurement obtained by producing a thin film including these nanoparticles onto a glass substrate with an ITO film formed thereon, followed by measurement through photoelectron spectroscopy or photoelectron yield spectroscopy (PYS). A nanoparticle's band gap value is a calculation obtained by measuring the photo-absorption spectrum of a thin film including these nanoparticles, followed by calculation through Tauc plotting. In a light-emitting nanoparticle, such as the blue nanoparticle 352b, its band gap may be a light-emission wavelength value converted into energy. Each nanoparticle's CBM value is a value obtained by subtracting the band gap from the foregoing VBM value.

As illustrated in FIG. 3, the electron transport layer 37 includes quantum dots 371 as an electron-transporting material. The quantum dots 371 each include a nanoparticle 372 (nanoparticle) containing a metal oxide, and a ligand 373 containing a thiol group that can coordinate with the nanoparticle 372.

The nanoparticles 372 preferably have an average particle diameter of 5 nm or smaller. The band gap between the CBM and VBM of the nanoparticle 372 is increased by a quantum effect along with decrease in the particle diameter of the nanoparticle 372. In contrast, the VBM value of the nanoparticle 372 does not change substantially even when the particle diameter of the nanoparticle 372 varies. As such, the CBM value is decreased by the quantum effect along with decrease in the particle diameter of the nanoparticle 372. The nanoparticles 372, when containing zinc oxide (ZnO) and having an average particle diameter of 5 nm or smaller for instance, have a CBM value of 2.7 eV or smaller. The CBM values of the blue nanoparticles 352b are often 2.7 eV or greater, as indicated in Table 1. Electrons move easily from the electron transport layer 37 to the blue light-emitting layer 35b when the CBM value of the nanoparticle 372 coincides with the CBM value of the blue nanoparticle 352b or is smaller than the CBM value of the blue nanoparticle 352b. It is hence preferable that the nanoparticles 372 have a CBM value of 2.7 eV or smaller, and that the nanoparticles 372 have an average particle diameter of 5 nm or smaller. An average particle diameter in the Description is a designed value of particle diameter, or a median value of particle diameter measured through a dynamic light scattering method.

The CBM values of nanoparticles included in a light-emitting layer tend to be smaller as the light emission wavelength of the light-emitting layer is shorter. To be specific, the blue light-emitting layer 35b has the shortest light emission wavelength and the smallest CBM value of the blue light-emitting layer 35b, green light-emitting layer and red light-emitting layer. Thus, when moving easily from the electron transport layer 37 to the blue light-emitting layer 35b, electrons move easily from the electron transport layer 37 also to the green light-emitting layer and the red light-emitting layer.

When the particle diameters of the nanoparticles 372 are less than 1 nm, the variation of the particle diameters is greater compared to the average of the particle diameters, and their band gaps change sensitively in response to the differences between the particle diameters. It is hence difficult to manufacture a plurality of nanoparticles 372 in such a manner that the variation of their band gaps is sufficiently small. The nanoparticles 372 thus preferably have a particle diameter of 1 nm or greater.

The nanoparticles 372 preferably contain a metal oxide that is suitable for electron transport so that an electron can move from one nanoparticle 372 to another nanoparticle 372. Such a metal oxide may be, for instance, at least one selected from the group consisting of zinc oxide (ZnO), titanium dioxide (TiO₂), tin dioxide (SnO₂), nickel oxide (NiO), zirconium dioxide (ZrO₂), tungsten trioxide (WO₃) and tantalum pentoxide (Ta₂O₅) or may be, for instance, a mixed crystalline substance containing at least one selected from this group.

The ligand 373 preferably contains a compound including a compound having only one thiol group per molecule. The ligand 373 preferably contains a compound having an odd number of carbon atoms per molecule. The ligand 373 preferably contains a compound having three or more and seven or less carbon atoms per molecule.

The ligand 373 preferably contains a compound including a benzene ring with which a thiol group is bonded directly. The ligand 373 is preferably para-toluenethiol (p-Toluenethiol) for instance.

The ligand 373 preferably contains at least one selected from the group consisting of compounds that are expressed by the following structural formulas (1) to (6):

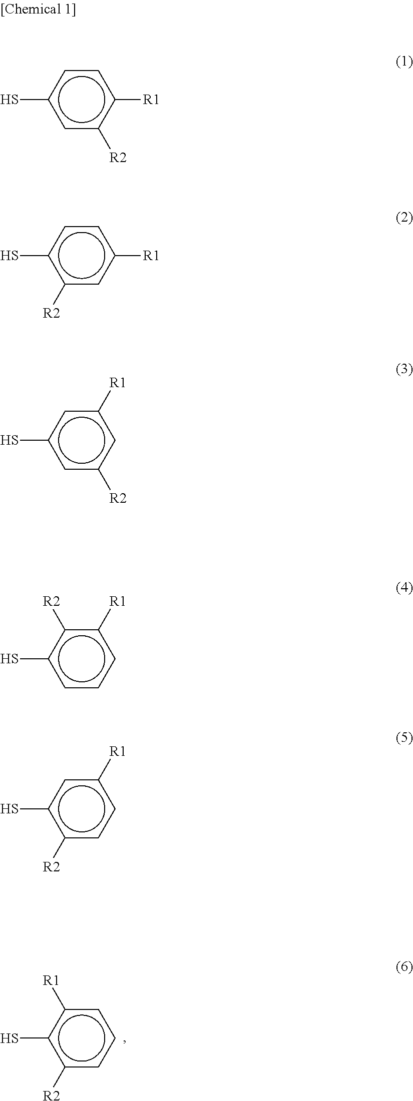

where SH denotes a thiol group, where R1 and R2 each independently denote any of a hydrogen atom, a methyl group, a methoxy group, an ethyl group and a propyl group, where at least one of R1 and R2 denotes any of a methyl group, an ethyl group and a propyl group.

The ligand 373 preferably contains at least one selected from the group consisting of compounds that are expressed by the following structural formulas (1) to (2):

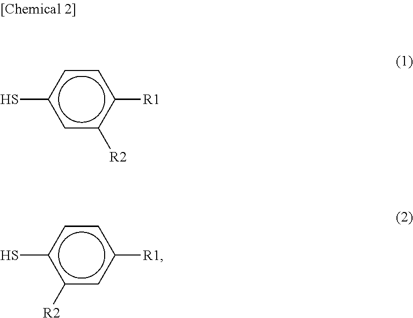

where SH denotes a thiol group, where R1 denotes any of a methyl group, a methoxy group, an ethyl group and a propyl group, where R2 denotes any of a methyl group, an ethyl group and a propyl group.

The ligand 373 preferably contains at least one selected from the group consisting of compounds that are expressed by the following structural formulas (7) to (9):

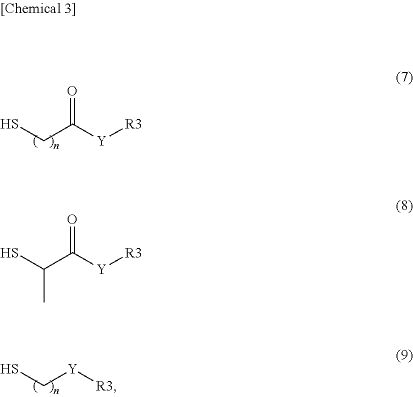

where SH denotes a thiol group, where Y denotes an oxygen atom (—O—) or an imino group (—NH—), where R3 denotes a substituted or non-substituted alkyl group having one or more and nine or less carbon atoms, where n denotes one or two.

The ligand 373 preferably includes, for instance, at least one selected from the group consisting of 3-mercaptopropionic acid methyl, 3-mercaptopropionic acid ethyl, 3-mercaptopropionic acid butyl, 3-mercaptopropionic acid isooctyl, 3-mercapto-N-nonylpropionamide, thioglycolic acid methyl, thioglycolic acid ethyl, thioglycolic acid 2-ethylhexyl and 2-(butylamino) ethanethiol.

The reason why the foregoing are preferable for the ligand 373 will be described later on.

Although not shown, the light-emitting element layer 5 according to the first embodiment includes, instead of the blue light-emitting layer 35b, a green light-emitting layer in the green subpixel Pg, and a red light-emitting layer in the green subpixel Pg.

Method for Manufacturing Light-Emitting Element

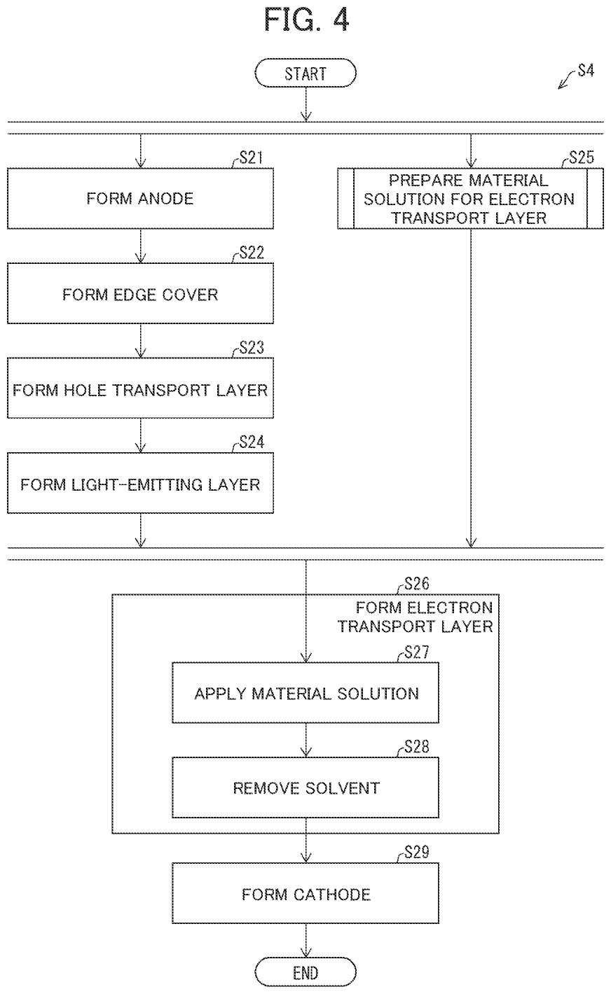

The following details a method for producing the light-emitting element ES illustrated in FIG. 3, with reference to FIG. 4 to FIG. 7.

FIG. 4 is a flowchart showing an example method for producing the light-emitting element ES illustrated in FIG. 3. The method for producing the light-emitting element ES corresponds to the step (Step S4) of forming the light-emitting element layer 5 shown in FIG. 1.

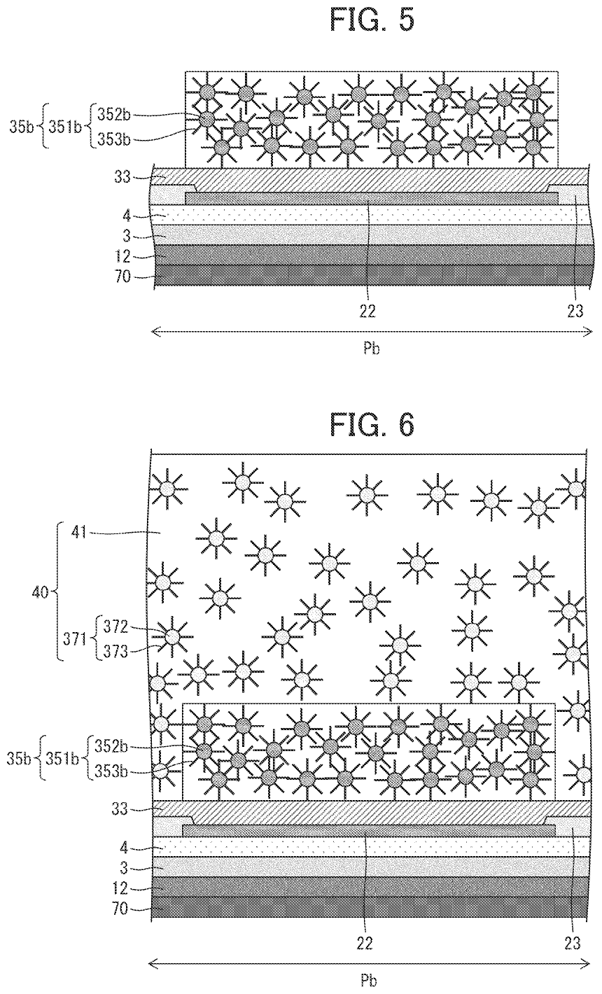

FIG. 5 to FIG. 7 each illustrate, in sectional view, an example method for producing the light-emitting element ES illustrated in FIG. 3.

As illustrated in FIG. 4 and FIG. 5, the first process step (Step S21) is forming the anode 22 for each pixel onto a matrix substrate including a mother glass 70 (substrate), resin layer 12, barrier layer 3 and thin-film transistor layer 4, followed by forming the edge cover 23 (Step S22) so as to cover the edge of the anode 22. The next (Step S23) is forming the hole transport layer 33 onto the anode 22 and edge cover 23, followed by forming a light-emitting layer (Step S24) for each pixel onto the hole transport layer 33. Step S24 includes forming, in any given order, the blue light-emitting layer 35b in the blue subpixel Pb, a green light-emitting layer in the green subpixel Pg, and a red light-emitting layer in the red subpixel Pr. Step S24 includes patterning each of the blue light-emitting layer 35b, green light-emitting layer and red light-emitting layer through any given technique, such as photolithography.

Further, a material solution 40, which is used for the electron transport layer 37, is prepared separately (Step S25) so as to contain a solvent 41 and the quantum dots 371 dispersed within the solvent 41.

Step S24 and Step S25 is followed by forming the electron transport layer 37 (Step S26) onto the hole transport layer 33, blue light-emitting layer 35b, green light-emitting layer and red light-emitting layer.

As illustrated in FIG. 4 and FIG. 6, Step S26 includes, firstly, applying the material solution 40 (Step S27) onto the substrate entirely, that is, onto the hole transport layer 33, the blue light-emitting layer 35b, the green light-emitting layer and the red light-emitting layer. The application may use any given method, such as spin coating, bar-coating or spraying.

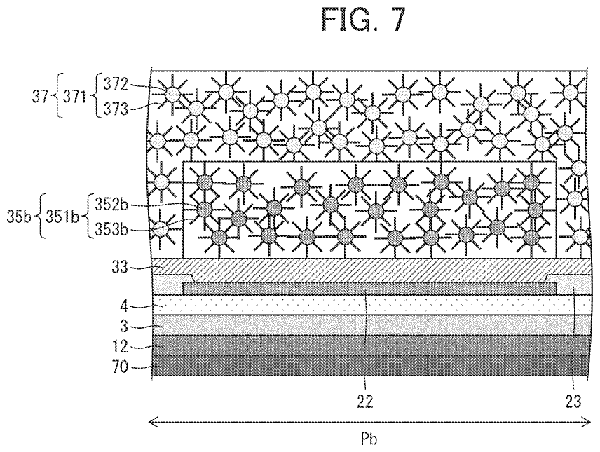

The next (Step S28) is removing the solvent 41 from the material solution 40 by vaporizing the solvent 41, as illustrated in FIG. 4 and FIG. 7. The vaporization of the solvent 41 may be promoted by heating the matrix substrate. The material solution 40 with the solvent 41 now lost turns into the electron transport layer 37.

The next (Step S29) is forming the cathode 25 onto the electron transport layer 37 entirely.

As described above, the light-emitting element ES is formed by performing Steps S21 through S29.

Method for Preparing Material Solution for Electron Transport Layer

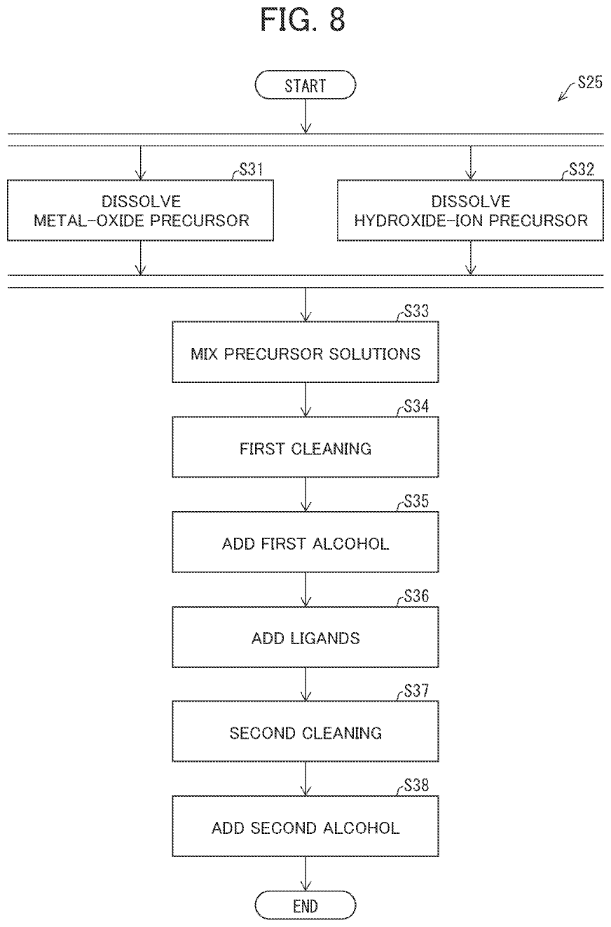

The following details a method for preparing the material solution 40 illustrated in FIG. 6, with reference to FIG. 8. The method for preparing the material solution 40 corresponds to the step (Step S25) of preparing the material solution 40 shown in FIG. 4.

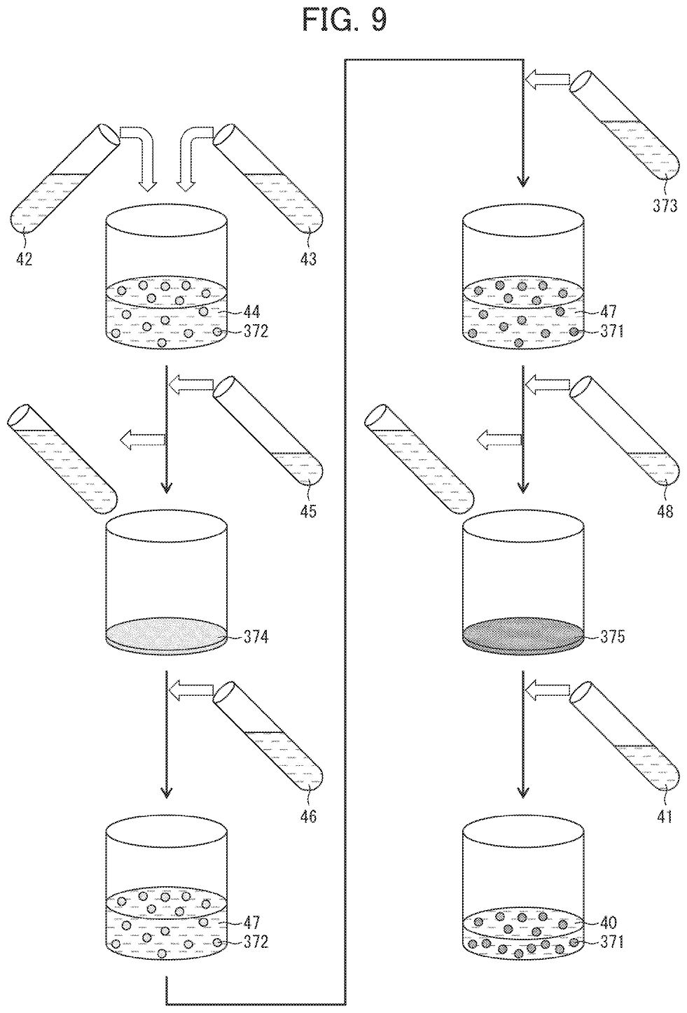

FIG. 8 is a flowchart showing an example process step (Step S25) of preparing the material solution 40 for the electron transport layer 37 shown in FIG. 4. FIG. 9 schematically illustrates the example process step of preparing the material solution for the electron transport layer shown in FIG. 4.

As illustrated in FIG. 8, a metal-oxide precursor is dissolved into a solvent to obtain a metal-oxide precursor solution 42 (Step S31). The metal-oxide precursor is a supply source of metal ions of the metal oxide contained in the nanoparticles 372 of the quantum dots 371 within the material solution 40. The metal-oxide precursor thus preferably contains metal ions and a negatively ionized acid. Further, the negatively ionized acid is preferably acetate ions or chloride ions. An example of the metal-oxide precursor may be zinc acetate when the nanoparticles 372 contain ZnO. Further, the solvent is a substance other than water and is preferably a non-aqueous polar solvent, such as dimethyl sulfoxide (DMSO), or a bipolar solvent, such as methanol or ethanol.

Further, a hydroxide-ion precursor solution 43 is obtained (Step S32) by dissolving a hydroxide-ion precursor into a solvent, before or after Step S31 or in parallel with Step S31. The hydroxide-ion precursor is a supply source of hydroxide ions. The hydroxide-ion precursor thus preferably contains a positively ionized base and hydroxide ions. Further, the positively ionized base preferably contains at least one selected from the group consisting of a polyatomic ion that is expressed by a structural formula (10) below, a lithium ion and a potassium ion. An example of the hydroxide-ion precursor may be tetra-methyl-ammonium hydroxide (TMAH). The solvent is a substance other than water and is preferably a non-aqueous polar solvent, such as DMSO, or a bipolar solvent, such as methanol or ethanol.

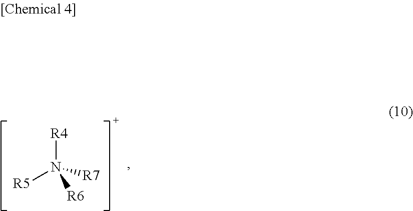

where R4 denotes a methyl group or an ethyl group, where R5, R6 and R7 each independently denote a hydrogen atom, a methyl group or an ethyl group.

Steps S31 and S32 are followed by a reaction step (Step S33) of mixing the metal-oxide precursor solution 42 and the hydroxide-ion precursor solution 43 together to obtain a mixed solution 44 (first solution). Metal acid ions are caused to react with hydroxide ions within the mixed solution 44 to obtain a metal hydroxide, followed by a dehydration reaction to obtain a metal oxide. Let the metal-oxide precursor be zinc acetate, and let the hydroxide-ion precursor be TMAH for instance; accordingly, a reaction that is expressed by a reaction formula (1) below occurs, thus generating zinc hydroxide. The next is a dehydration reaction that is expressed by a reaction formula (2) below, thus generating zinc oxide nanoparticles.

Zn(CH₃COO)₂+2N(CH₃)₄·OH→Zn(OH)₂+2N(CH₃)₄·(CH₃COO) (1)

Zn(OH)₂→ZnO+H₂O (2)

Then, the foregoing two-stage reaction is continued by letting the mixed solution 44 stand for a while, to thus grow metal-oxide nanoparticles. The metal-oxide nanoparticles grow further and have a larger particle diameter as the time for letting the solution stand increases. The metal-oxide nanoparticles are the nanoparticles 372 in the electron transport layer 37. It is thus preferable to determine the time for letting the solution stand in accordance with the particle diameter of the nanoparticle 372 in the electron transport layer 37.

The next (Step S34, first cleaning step) is cleaning the mixed solution 44 by using a solvent 45 of at least one selected from the group consisting of acetone, ethyl acetate, butyl acetate, hexane, octane, toluene and methanol. The nanoparticles 372 are turned into a precipitation 374 by this cleaning. The cleaning, although may be performed one time, is preferably performed a plurality of times. The following describes, by way of example, an instance where the metal-oxide precursor is zinc acetate, and where the hydroxide-ion precursor is TMAH. Zinc oxide nanoparticles, which do not disperse in ethyl acetate, turn into a precipitation when an excessive amount of ethyl acetate is added into a solution. Zinc acetate and TMAH in contrast, which dissolve in ethyl acetate, do not turn into a precipitation. Separating a precipitation from a solution through, for instance, centrifugal separation and removing only the solution can remove zinc acetate and TMAH, thus obtaining only zinc oxide nanoparticles. It is noted that centrifugal separation is a non-limiting method; a solvent may be removed together with zinc acetate and TMAH through heating or pressure reduction.

Unreacted metal ions and the hydroxide-ion precursor are removed from the mixed solution 44 by the foregoing cleaning, thereby stopping the generation of a metal hydroxide, and then stopping the generation of a metal oxide. Then, increase in the particle diameters of the nanoparticles 372 that result from the generation of the metal oxide stops. It should be noted increase in the particle diameters of the nanoparticles 372 that results from aggregation or Ostwald ripening continues.

The next (Step S35, part of the first addition step) is adding an alcohol 46 (first alcohol), such as ethanol or butanol, into the precipitation 374 of the metal-oxide nanoparticles (i.e., the nanoparticles 372) to thus obtain a solution 47 (second solution). The added alcohol disperses the nanoparticles 372 and avoids the aggregation of the nanoparticles 372.

The next (Step S36, part of the first addition step) is adding the ligands 373 or a solution containing the ligands 373 into the solution 47. The ligands 373 coordinate with the nanoparticles 372 to avoid the aggregation and Ostwald ripening of the nanoparticles 372. Further, the quantum dots 371 including the nanoparticles 372 and the ligands 373 are generated.

The next (Step S37, second cleaning step) is cleaning the solution 47 by using a solvent 48 of at least one selected from the group consisting of hexane, octane and toluene. The quantum dots 371, which include the nanoparticles 372, do not disperse in this solvent and turns into a precipitation 375. In contrast, the ligands 373 dissolve in the solvent 48. Separating the precipitation from the solution through, for instance, centrifugal separation and removing only the solution can remove excess ligands 373 that are not coordinating with the nanoparticles 372. This cleaning, although may be performed one time, is preferably performed a plurality of times. It is noted that centrifugal separation is a non-limiting method; the solvent may be removed together with the excess ligands 373 through heating or pressure reduction.

The last (Step S38, the second addition step) is adding, as the solvent 41, an alcohol (second alcohol), such as ethanol or butanol, to the precipitation 375 of the quantum dots 371 to thus obtain the material solution 40 (third solution) for the electron transport layer 37. The added alcohol disperses the quantum dots 371 and avoids the aggregation of the nanoparticles 372. The quantum dots 371 disperse within the alcohol, thereby enabling the foregoing application in Step S28 to be performed easily, and enables increase in the average particle diameter of the nanoparticles 372 to be prevented.

It is noted that the alcohol that is to be added in Step S38 may be the same as or different from the alcohol that is to be added in Step S35. For a different alcohol, it is preferable to, for instance, add ethanol in Step S35 and add butanol in Step S38. This is because that the ethanol's boiling point (78 degrees centigrade) is lower than the butanol's boiling point (117 degrees centigrade). Ethanol, which has a lower boiling point, is removed easily together with a solvent when the solvent undergoes heating or pressure reduction in Step S37 for removal. Butanol in contrast, which has a higher boiling point, allows the electron transport layer 37 to be formed uniformly from the material solution 40 in Step S28.

The material solution 40 for the electron transport layer 37 thus contains, as the solvent 41, the alcohol added in Step S38 and further contains the quantum dots 371 dispersed within the solvent 41. It is noted that the method of preparing the material solution 40 according to the first embodiment is not limited to the method shown in FIG. 8 and FIG. 9; any suitable method may be used.

Ligand

The ligand 373 is a ligand that can coordinate with the nanoparticle 372, and the ligand 373 contains a thiol group, as described above.

The electronegativity of a sulfur atom (S: about 2.58) is smaller than the electronegativity of an oxygen atom and of a nitrogen atom (O: about 3.44, N: about 3.04). The polarity of a ligand containing a thiol group (—SH) is thus smaller than the polarity of a ligand containing a hydroxy group (—OH) or an amino group (—NH₂). Thus, the hydrogen bonding between ligands containing a thiol group is relatively weak, and the space between the ligands containing the thiol group is relatively wide. The space between the nanoparticles is consequently relatively wide in a layer including the ligands containing the thiol group, and the nanoparticles are relatively less likely to exhibit aggregation and Ostwald ripening. An example of the ligand containing the amino group is ethanolamine.

A carboxyl group (—COOH) acts as an acid to elute metal ions from nanoparticles containing a metal oxide. A thiol group in contrast does not act as an acid. Hence, nanoparticles containing a metal oxide in a layer including ligands containing a thiol group are less likely to dissolve than nanoparticles containing a metal oxide in a layer including ligands containing a carboxyl group. Nanoparticles containing a metal oxide in a layer including ligands containing a thiol group can consequently exist relatively stably. An example of the ligands containing the carboxyl group is oleic acid.

As such, the nanoparticles 372 included in the electron transport layer 37 in the configuration according to the first embodiment are less likely to exhibit aggregation and Ostwald ripening. Hence, the particle diameters of the nanoparticles 372 are less likely to increase, and the band gaps of the nanoparticles 372 are less likely to decrease. The CBM value of each nanoparticle 372 is smaller along with increase in the band gap of the nanoparticle 372. A smaller CBM value of the nanoparticle 372 is more advantageous for electron injection from the electron transport layer 37 into the blue light-emitting layer 35b, the green light-emitting layer and the red light-emitting layer. The configuration according to the first embodiment thus exerts an effect, i.e., improving the light emission efficiency of a light-emitting element.

The ligand 373 preferably contains a compound having only one thiol group per molecule. A compound having only one thiol group has a smaller polarity than a compound having two or more thiol groups. Hence, the hydrogen bonding between compounds containing only one thiol group is relatively weak. It is consequently preferable that the ligand 373 contain a compound having only one thiol group per molecule so that the particle diameter of the nanoparticle 372 included in the electron transport layer 37 is less likely to increase.

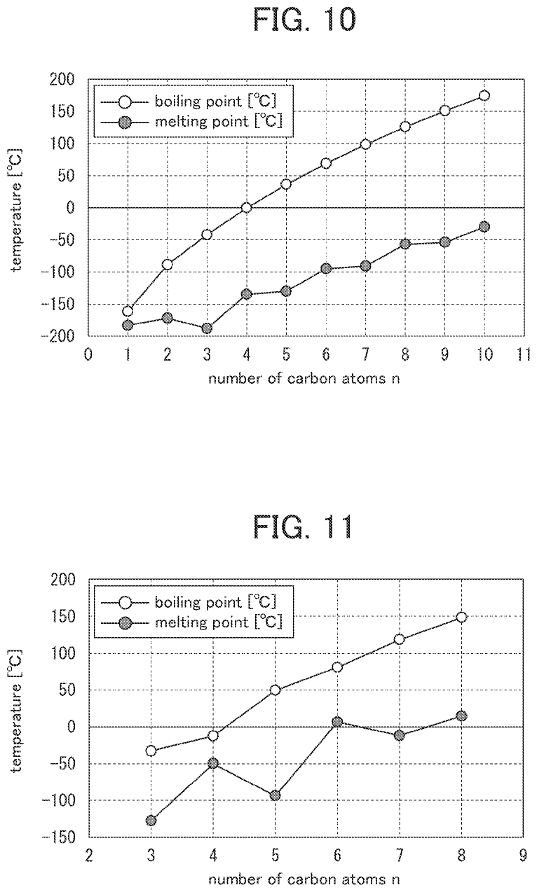

The ligand 373 preferably contains a compound having an odd number of carbon atoms per molecule. As illustrated in FIG. 10 and FIG. 11, an even or odd number of carbon atoms of alkane and cycloalkane does not affect boiling point, but affects melting point. The melting points of alkane and cycloalkane having an odd number of carbon atoms tend to be lower than the melting points of alkane and cycloalkane having an even number of carbon atoms. Typically in organic compounds, a compound having an even number of carbon atoms tends to have a higher filling rate and higher stability in a solid state and to have a shorter molecule-to-molecule distance than a compound having an odd number of carbon atoms due to the symmetry of molecules. It is thus preferable that the ligand 373 contain a compound having an odd number of carbon atoms per molecule so that the particle diameter of the nanoparticle 372 included in the electron transport layer 37 is less likely to increase.

FIG. 10 is a graph showing the boiling point and melting point of straight-chain alkane (CₙH₂ₙ₊₂). FIG. 11 is a graph showing the boiling point and melting point of annular cycloalkane (CₙH₂ₙ). In each of FIG. 10 and FIG. 11, the lateral axis indicates the number n of carbon atoms, and the vertical axis indicates temperature (centigrade).

The ligand 373 preferably contains a compound having three or more carbon atoms per molecule.

A non-substituted hydrocarbon molecule is apolar. A compound that is included as a ligand thus tends to have a longer molecular length and a smaller polarity along with increase in the number of its carbon atoms. Hence, the particle diameter of a nanoparticle is less likely to increase in a layer including, as a ligand, a compound having many carbon atoms. It is thus preferable that the ligand 373 contain a compound having many carbon atoms per molecule.

An experiment has shown that the particle diameter of the nanoparticle 372 tends to increase in the electron transport layer 37 according to Comparative Example 1 containing ethanolamine (HO—C₂H₄—NH₂, two carbon atoms) as the ligand 373. The ligand 373 thus preferably contains a compound having three or more carbon atoms per molecule.

The ligand 373 preferably contains a compound having seven or less carbon atoms per molecule.

Many light-emitting materials that are contained in a light-emitting layer are less likely to dissolve or disperse in a polar solvent and are more likely to dissolve or disperse in an apolar solvent. For instance, the blue quantum dot 351b is less likely to disperse in a polar solvent and is more likely to disperse in an apolar solvent. Further, the electron transport layer 37 often comes into direct contact with a light-emitting layer. As illustrated in FIG. 3 for instance, the electron transport layer 37 is in direct contact with the blue light-emitting layer 35b. As earlier described, the electron transport layer 37 is formed by, as illustrated in FIG. 6, applying the material solution 40 with the quantum dots 371 dispersed in the solvent 41 onto the light-emitting layers, such as the blue light-emitting layer 35b, and by, as illustrated in FIG. 7, vaporizing the solvent 41 from the material solution 40. As such, the interface between the light-emitting layers and the electron transport layer 37 becomes flat and clear when the solvent 41 is a polar solvent. That the interface between the light-emitting layers and the electron transport layer 37 is flat and clear contributes to improvement in the light emission efficiency of the light-emitting element. It is thus preferable that the solvent 41 be a polar solvent, and that the quantum dots 371 and the ligands 373 easily disperse in the polar solvent.

Furthermore, the material solution 40 can be cleaned using a non-polar solvent when the quantum dots 371 and the ligands 373 easily disperse in a polar solvent.

Among organic compounds containing straight-chain alkane and a single thiol group, octanethiol having eight carbon atoms and a compound having nine or more carbon atoms are less likely to disperse in a polar solvent. Heptanethiol having seven carbon atoms and a compound having six or less carbon atoms in contrast easily disperse in a polar solvent. The ligand 373 thus preferably contains a compound having seven or less carbon atoms per molecule so that the quantum dots 371 easily disperse in a polar solvent.

The ligand 373 preferably contains a compound including a benzene ring with which a thiol group is bonded directly. Compounds each including a benzene rings are arranged by a n-n interaction. The number of ligands 373 coordinating with the nanoparticle 372 (i.e., the number of coordinating ligands) thus tends to be relatively large when a compound including a benzene ring with which a thiol group is bonded directly is contained as the ligand 373. The particle diameter of the nanoparticle 372 is less likely to increase along with increase in the number of coordinating ligands. The particle diameter of the nanoparticle 372 included in the electron transport layer 37 is consequently less likely to increase.

The ligand 373 preferably contains at least one selected from the group consisting of compounds that are expressed by the following structural formulas (1) to (6):

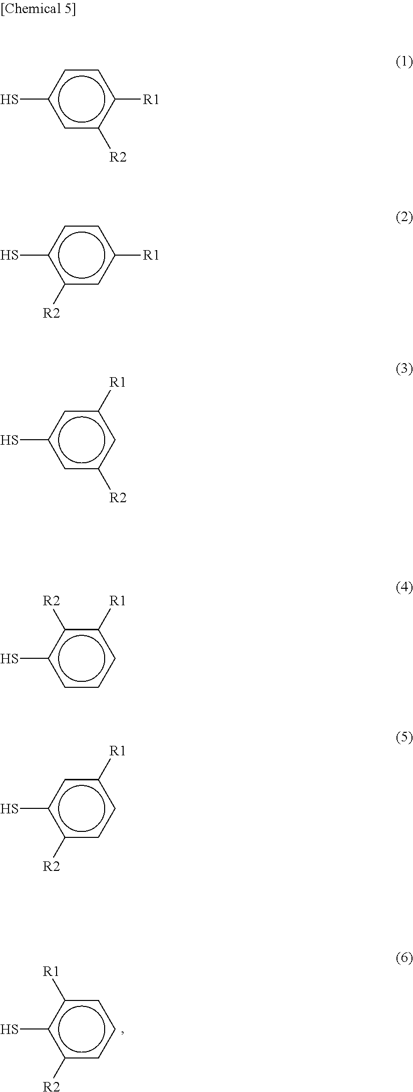

where SH denotes a thiol group, where R1 and R2 each independently denote any of a hydrogen atom, a methyl group, a methoxy group, an ethyl group and a propyl group, where at least one of R1 and R2 denotes any of a methyl group, an ethyl group and a propyl group.

Compounds each including a benzene rings substituted, in at least one location, by a methyl group, an ethyl group or a propyl group are arranged by a n-n interaction in such a manner that their benzene rings are in parallel with each other. Hence, the number of ligands 373 coordinating with the nanoparticle 372 tends to be larger. The particle diameter of the nanoparticle 372 included in the electron transport layer 37 is consequently less likely to increase.

The ligand 373 further preferably contains at least one selected from the group consisting of compounds that are expressed by the following structural formulas (1) to (2):

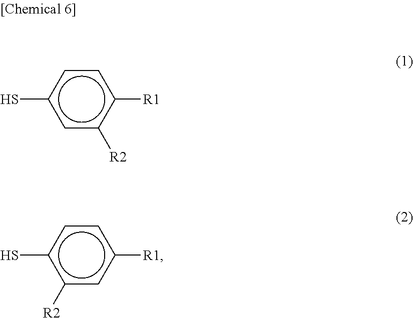

where SH denotes a thiol group, where R1 denotes any of a methyl group, an ethyl group and a propyl group, where R2 denotes any of a methyl group, an ethyl group and a propyl group.

R1, which is any of a methyl group, an ethyl group and a propyl group, serves as a larger steric barrier than a hydrogen atom and a methoxy group. R1, which is in para position with respect to the thiol group, is oriented opposite the nanoparticle 372 when the ligand 373 is coordinated to the nanoparticle 372 by the thiol group. One nanoparticle 372 and the ligand 373 coordinating with this nanoparticle 372 are hence less likely to approach another nanoparticle 372 coordinating with the ligand 373. Further, the ligands 373 are arranged by a 7E-7r interaction in such a manner that their benzene rings are in parallel with each other. The particle diameter of the nanoparticle 372 included in the electron transport layer 37 is consequently less likely to increase.

A preferably example of the ligand 373 is para-toluenethiol (p-Toluenethiol).

Further, the ligand 373 preferably contains at least one selected from the group consisting of compounds that are expressed by the following structural formulas (7) to (9):

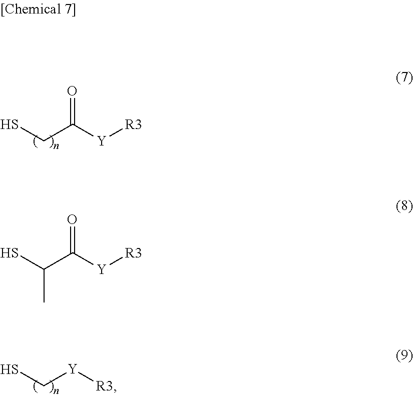

where SH denotes a thiol group, where Y denotes an oxygen atom or an imino group, where R3 denotes a substituted or non-substituted alkyl group having one or more and nine or less carbon atoms, where n denotes one or two.

An experiment has revealed that the ligands 373 avoid increase in the average particle diameter of the nanoparticles 372 when the ligands 373 contain at least one selected from the group consisting of 3-mercaptopropionic acid methyl, 3-mercaptopropionic acid ethyl, 3-mercaptopropionic acid butyl, 3-mercaptopropionic acid isooctyl, 2-mercaptopropionic acid ethyl, 3-mercapto-N-nonylpropionamide, thioglycolic acid methyl, thioglycolic acid ethyl, thioglycolic acid 2-ethylhexyl and 2-(butylamino) ethanethiol.

### Example 1

A light-emitting element according to Example 1 was produced where its configuration was different from the configuration illustrated in FIG. 3 only in that the hole injection layer 31 was disposed between the anode 22 and the hole transport layer 33.

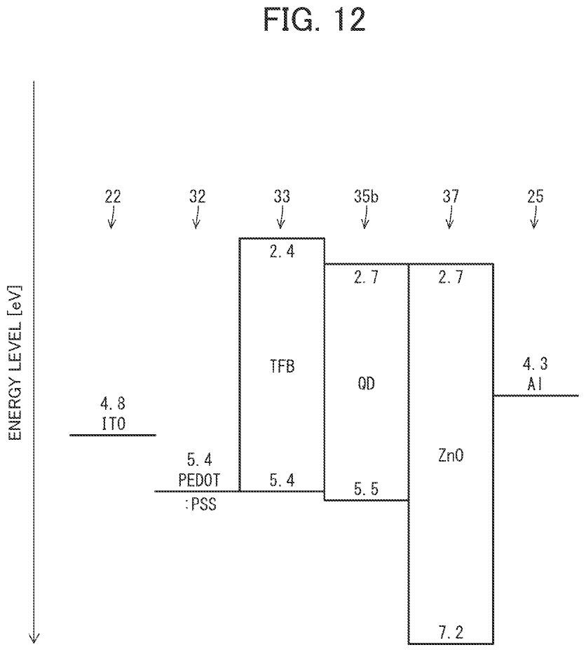

FIG. 12 is a schematic diagram of the energy level of the light-emitting element according to Example 1.

The light-emitting element according to Example 1 includes, sequentially on the substrate, the anode 22, the hole injection layer 31, the hole transport layer 33, the blue light-emitting layer 35b, the electron transport layer 37, and the cathode 25.

The anode 22 contained indium tin oxide (ITO), was 30 nm thick and had a Fermi level value of 4.8 eV, as illustrated in FIG. 12. In the Description, a Fermi level value is the difference (i.e., absolute value) between the electron's energy level and electron's Fermi level in a vacuum.

The hole injection layer 31 contained poly(3,4-ethylenedioxythiphene):poly(styrene-sulfonate) (PEDOT:PSS), was 40 nm thick and had a Fermi level value of 5.4 eV.

The hole transport layer 33 contained poly(9,9-dioctylflour-ene-co-N(4-butylphenyl)-diphenylamine (TFB), was 30 nm thick and had a VBM value of 5.4 eV and a CBM value of 2.4 eV.

The blue light-emitting layer 35b included the blue nanoparticles 352b of core-shell structure and was 30 nm thick. The blue nanoparticles 352b had an average particle diameter of 10 nm, each had a core-shell of ZnSe—ZnS and had a VBM value of 5.5 eV and a CBM value of 2.7 eV.

The electron transport layer 37 according to Example 1 included the nanoparticles 372 of ZnO and the ligands 373 and was 50 nm thick. The nanoparticles 372 had an average particle diameter of 2.5 nm and had a VBM value of 7.2 eV and a CBM value of 2.7 eV. The ligands 373 were para-toluenethiol (p-Toluenethiol). It is noted that the average particle diameter, VBM value and CBM value described in this paragraph and FIG. 12 are values at the time point of a confirmation that the band gap between the VBM and CBM is stable.

The cathode 25 contained aluminum, was 100 nm thick and had a Fermi level value of 4.3 eV.

The light-emitting element according to Example 1 was produced through the production method described above with reference to FIG. 4 to FIG. 8.

To be specific, 0.1 mol/l of zinc acetate DMSO solution was produced in Step S31 by dissolving zinc acetate in DMSO at 60 degrees centigrade and filtering it. Further, 0.5 mol/l of TMAH methanol solution was produced in Step S32 by dissolving TMAH in methanol. Then in Step S33, 10 ml of the zinc acetate DMSO solution and 2 ml of the TMAH methanol solution were mixed together, and the mixture was left to stand for 5 minutes at room temperature (20 degrees centigrade). Next, the solution was cleaned twice by ethyl acetate in Step S34. Next, 3 ml of butanol was added in Step S35, and 300 μl of para-toluenethiol was added in Step S36 as the ligands 373. Then, the solution was cleaned twice by hexane in Step S37, and 1 ml of butanol was added in Step S38.

### Example 2

A light-emitting element according to Example 2 is different from the foregoing light-emitting element according to Example 1 only in that 300 μl of 3-mercaptopropionic acid butyl has been added in Step S36 as the ligands 373. A compound of 3-mercaptopropionic acid butyl is expressed by a structural formula (11) below.

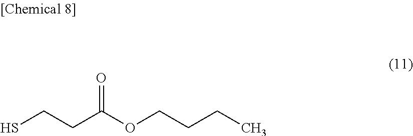

### Comparative Example 1

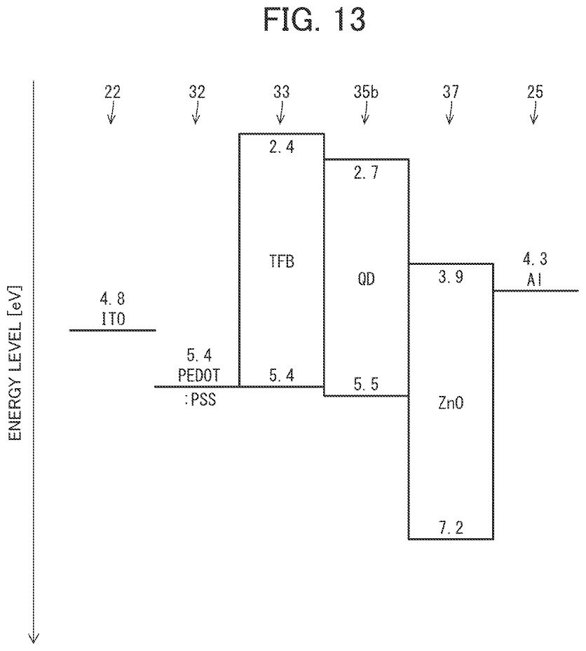

FIG. 13 is a schematic diagram of the energy level of a light-emitting element according to Comparative Example 1.

The light-emitting element according to Comparative Example 1 is different from the foregoing light-emitting element according to Example 1 only in that 300 μl of ethanolamine has been added in Step S36 as the ligands 373. Ethanolamine is a compound that is expressed by a structural formula (12) below. It is noted that the VBM value and CBM value shown in FIG. 13 are values at the time point of a confirmation that the band gap between the VBM and CBM is stable.

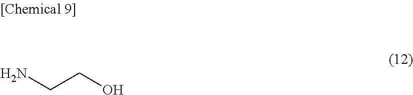

### Comparative Example 2

A light-emitting element according to Comparative Example 2 contained oleic acid as the ligands 373. However, oleic acid has many carbon atoms (C=18), and oleic acid no longer disperses in butanol, which is a polar solvent, and disperses in hexane, which is a non-polar solvent, when oleic acid coordinates with nanoparticles, as described above. Accordingly, hexane was added in Step S35 instead of butanol, and 300 μl of oleic acid was added in Step S36 as the ligands 373. Then, two-time cleaning was performed in Step S37 using ethanol instead of hexane, and 1 ml of hexane was added in Step S38. The light-emitting element according to Comparative Example 2 is different from the foregoing light-emitting element according to Comparative Example 1 only in that 300 μl of oleic acid has been added. Oleic acid is a compound that is expressed by a structural formula (13) below.

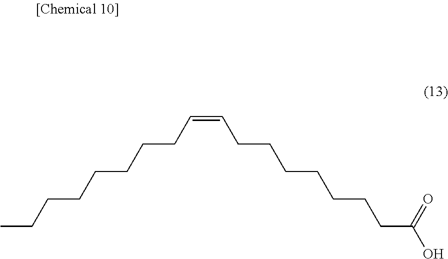 [SMILES: CCCCCCCC/C=C\CCCCCCCC(=O)O]

### Comparative Example 3

A light-emitting element according to Comparative Example 3 is different from the foregoing light-emitting element according to Comparative Example 1 only in that Step S36 has been omitted, in other words, the material solution 40 and the electron transport layer 37 contain no ligands that can coordinate with the nanoparticles 372.

Results of Measurement

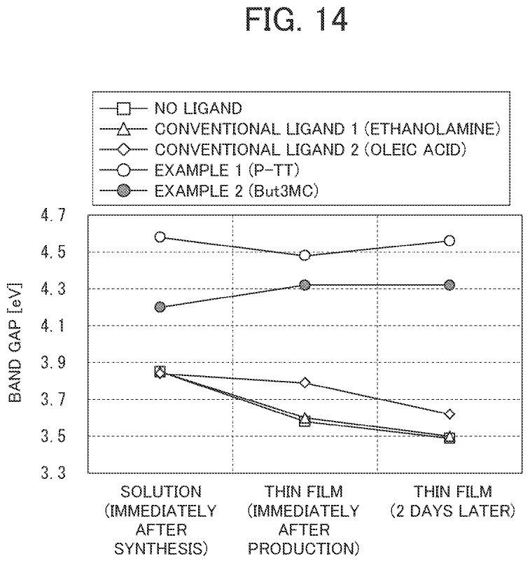

FIG. 14 is a graph showing band gap measurements of the nanoparticle 372 for each of the light-emitting elements according to Examples 1 and 2 and according to Comparative Examples 1 to 3. Each band gap value is the difference between a VBM value and a CBM value. Each band gap was measured three times. The first measurement was performed immediately after the preparation of the material solution 40, that is, immediately after the completion of Step S38, which is shown in FIG. 8. The second measurement was performed immediately after the formation of the electron transport layer 37, that is, immediately after the completion of Step S28, which is shown in FIG. 4. The third measurement was performed two days later from the formation of the electron transport layer 37, that is, 48 hours later from the completion of Step S28, which is shown in FIG. 4. In FIG. 14, the vertical axis indicates band gap values, and the lateral axis indicates measurement times.

As shown in FIG. 14, the band gap values of the nanoparticles 372 according to Examples 1 and 2 were already larger than the band gap values of the nanoparticles 372 according to Comparative Examples 1 to 3 at the time point of the preparation of the material solution 40. Further, the band gap values of the nanoparticles 372 according to Comparative Examples 1 and 2 were equal to the band gap value of the nanoparticle 372 according to Comparative Example 3. The light-emitting elements according to Examples 1 and 2 and according to Comparative Examples 1 to 3 are different in their ligands 373. The ligands 373 according to Examples 1 and 2 thus avoided the average particle diameter of the nanoparticles 372 from increase within the solution.

As illustrated in FIG. 14, the band gap values of the nanoparticles 372 according to Examples 1 and 2 did not substantially change from the formation of the electron transport layer 37 to the two days later. The band gap values of the nanoparticles 372 according to Comparative Examples 1 to 3 in contrast decreased. The ligands 373 according to Examples 1 and 2 thus avoided the average particle diameter of the nanoparticles 372 from increase also in the electron transport layer 37.

As a result, the light-emitting element according to Example 1 exhibited that the CBM value of the nanoparticle 372, included in the electron transport layer 37, was substantially equal to the CBM value of the blue nanoparticle 352b, included in the blue light-emitting layer 35b, as illustrated in FIG. 12. As a result, electron injection from the electron transport layer 37 into the blue light-emitting layer 35b is easy, and the light-emitting element has high light emission efficiency. Although not shown, the light-emitting element according to Example 2 has high light emission efficiency similarly.

The light-emitting element according to Comparative Example 1 in contrast exhibited that the CBM value of the nanoparticle 372, included in the electron transport layer 37, was lower than the CBM value of the blue nanoparticle 352b, included in the blue light-emitting layer 35b, as illustrated in FIG. 13. As a result, electron injection from the electron transport layer 37 into the blue light-emitting layer 35b is difficult, and the light-emitting element has low light emission efficiency. Although not shown, the light-emitting elements according to Comparative Examples 2 and 3 have low light emission efficiency similarly.

### SUMMARY

A light-emitting element according to a first aspect of the present invention includes the following: an anode; a cathode; a light-emitting layer disposed between the anode and the cathode; and an electron transport layer disposed between the anode and the light-emitting layer, wherein the electron transport layer includes a nanoparticle containing a metal oxide, and a ligand containing a thiol group.

The light-emitting element according to a second aspect of the present invention may be configured, in the configuration according to the first aspect, such that the ligand contains a compound having only one thiol group per molecule.

The light-emitting element according to a third aspect of the present invention may be configured, in the configuration according to the first or second aspect, such that the ligand contains a compound having an odd number of carbon atoms per molecule.

The light-emitting element according to a fourth aspect of the present invention may be configured, in the configuration according to any one of the first to third aspects, such that the ligand contains a compound having three or more and seven or less carbon atoms per molecule.

The light-emitting element according to a fifth aspect of the present invention may be configured, in the configuration according to any one of the first to fourth aspects, such that the ligand contains a compound including a benzene ring with which the thiol group is bonded directly.

The light-emitting element according to a sixth aspect of the present invention may be configured, in the configuration according to any one of the first to fourth aspects, such that the ligand contains at least one selected from the group consisting of compounds that are expressed by the following structural formulas (1) to (6):

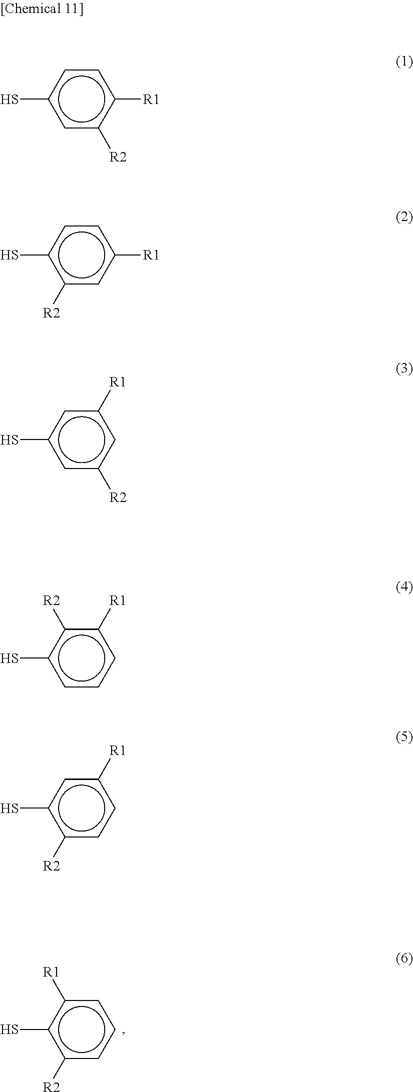

where SH denotes the thiol group, where R1 and R2 each independently denote any of a hydrogen atom, a methyl group, a methoxy group, an ethyl group and a propyl group, where at least one of R1 and R2 denotes any of a methyl group, an ethyl group and a propyl group.

The light-emitting element according to a seventh aspect of the present invention may be configured, in the configuration according to any one of the first to fourth aspects, such that the ligand contains at least one selected from the group consisting of compounds that are expressed by the following structural formulas (1) to (2):

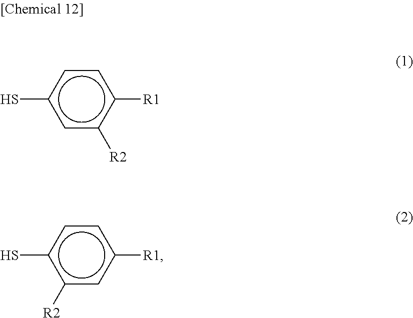

where SH denotes the thiol group, where R1 denotes any of a methyl group, an ethyl group and a propyl group, where R2 denotes any of a hydrogen atom, a methyl group, a methoxy group, an ethyl group and a propyl group.

The light-emitting element according to an eighth aspect of the present invention may be configured, in the configuration according to any one of the first to fourth aspects, such that the ligand is para-toluenethiol (p-Toluenethiol).

The light-emitting element according to a ninth aspect of the present invention may be configured, in the configuration according to any one of the first to third aspects, such that the ligand contains at least one selected from the group consisting of compounds that are expressed by the following structural formulas (7) to (9):

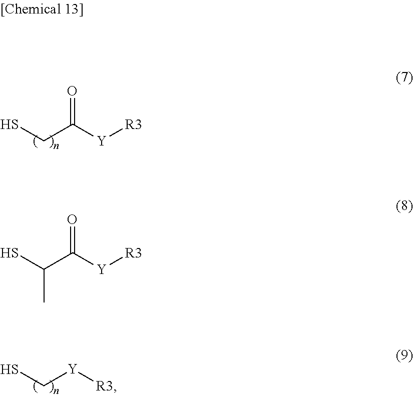

where SH denotes the thiol group, where Y denotes an oxygen atom or an imino group, where R3 denotes a substituted or non-substituted alkyl group having one or more and nine or less carbon atoms, where n denotes one or two.

The light-emitting element according to a tenth aspect of the present invention may be configured, in the configuration according to any one of the first to fourth aspects, such that the ligand contains at least one selected from the group consisting of 3-mercaptopropionic acid methyl, 3-mercaptopropionic acid ethyl, 3-mercaptopropionic acid butyl, 3-mercaptopropionic acid isooctyl, 2-mercaptopropionic acid ethyl, 3-mercapto-N-nonylpropionamide, thioglycolic acid methyl, thioglycolic acid ethyl, thioglycolic acid 2-ethylhexyl and 2-(butylamino) ethanethiol.

The light-emitting element according to an eleventh aspect of the present invention may be configured, in the configuration according to any one of the first to tenth aspects, such that the nanoparticle has an average particle diameter of 1 to 5 nm inclusive.

The light-emitting element according to a twelfth aspect of the present invention may be configured, in the configuration according to any one of the first to eleventh aspects, such that the metal oxide contains at least one selected from the group consisting of zinc oxide, titanium dioxide, tin dioxide, nickel oxide, zirconium dioxide, tungsten trioxide and tantalum pentoxide.

The light-emitting element according to a thirteenth aspect of the present invention may be configured, in the configuration according to any one of the first to twelfth aspects, such that the light-emitting layer includes a quantum dot configured to emit blue light.

A display device according to a fourteenth aspect of the present invention may include the light-emitting element according to any one of the first to thirteenth aspects.

A lighting device according to a fifteenth aspect of the present invention may include the light-emitting element according to any one of the first to thirteenth aspects.

A method for producing a light-emitting element according to a sixteenth aspect of the present invention includes the following: a reaction step of causing a metal-oxide precursor to react with a hydroxide ion within a first solution to generate a nanoparticle including a metal oxide; a first addition step of generating, after the reaction step, a quantum dot including the nanoparticle and a ligand within a second solution in which a first alcohol and the ligand containing a thiol group are added to the nanoparticle; and an application step of applying a third solution containing the quantum dot onto a substrate after the first addition step.

The method for producing light-emitting element according to a seventeenth aspect of the present invention may further include, in the method according to the sixteenth aspect, a second addition step of further adding a second alcohol to the quantum dot after the first addition step.

The method for producing the light-emitting element according to an eighteenth aspect of the present invention may be configured, in the method according to the sixteenth or seventeen the aspect, such that the metal-oxide precursor contains a metal ion and a negatively ionized acid, and such that the hydroxide ion is contained in a hydroxide-ion precursor containing a positively ionized base.

The method for producing the light-emitting element according to a nineteenth aspect of the present invention may be configured, in the method according to the eighteenth aspect, such that the negatively ionized acid is at least one selected from the group consisting of an acetate ion and a chloride ion, and the positively ionized base contains at least one selected from the group consisting of a polyatomic ion that is expressed by the following structural formula (10), a lithium ion and a potassium ion:

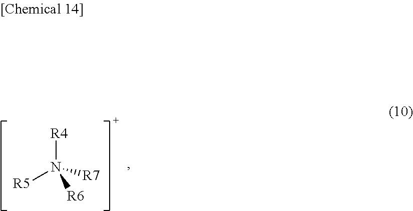

where R4 denotes a methyl group or an ethyl group, where R5, R6 and R7 each independently denote a hydrogen atom, a methyl group or an ethyl group.

The method for producing the light-emitting element according to a twentieth aspect of the present invention may further include, in the method according to the nineteenth aspect, between the reaction step and the first addition step, a first cleaning step of cleaning, the first solution by using at least one selected from the group consisting of acetone, ethyl acetate, butyl acetate, hexane, octane, toluene and methanol.

The method for producing the light-emitting element according to a twenty-first aspect of the present invention may be configured, in the method according to any one of the sixteenth to tenth aspects, such that the ligand contains a compound having three or more and seven or less carbon atoms per molecule, and such that the method further includes, between the first addition step and the application step, a second cleaning step of cleaning the second solution by using at least one selected from the group consisting of hexane, octane and toluene.

The present invention is not limited to the foregoing embodiments. Various modifications can be devised within the scope of the claims. An embodiment that is obtained in combination, as appropriate, with the technical means disclosed in the respective embodiments is also included in the technical scope of the present invention. Furthermore, combining the technical means disclosed in the respective embodiments can form a new technical feature.

### REFERENCE SIGNS LIST

22 anode (positive electrode)
25 cathode (negative electrode)
35b blue light-emitting layer (light-emitting layer)
351b blue quantum dot (quantum dot that emits blue light, quantum dot including nanoparticle and ligand)
37 electron transport layer
372 nanoparticle (nanoparticle containing metal oxide)
373 ligand (ligand containing thiol group)
40 material solution (third solution)
44 mixed solution (first solution)
46 alcohol (first alcohol)
47 solution (second solution)
48 alcohol (second alcohol)
70 mother glass (substrate)

1. A light-emitting element comprising:
an anode;
a cathode;
a light-emitting layer disposed between the anode and the cathode; and
an electron transport layer disposed between the anode and the light-emitting layer,
wherein the electron transport layer includes
a nanoparticle containing a metal oxide, and
a ligand containing a thiol group.

2. The light-emitting element according to claim 1, wherein the ligand contains a compound having only one thiol group per molecule.

3. The light-emitting element according to claim 1, wherein the ligand contains a compound having an odd number of carbon atoms per molecule.

4. The light-emitting element according to claim 1, wherein the ligand contains a compound having three or more and seven or less carbon atoms per molecule.

5. The light-emitting element according to claim 1, wherein the ligand contains a compound including a benzene ring with which the thiol group is bonded directly.

6. The light-emitting element according to claim 1, wherein
the ligand contains at least one selected from the group consisting of compounds that are expressed by the following structural formulas (1) to (6): 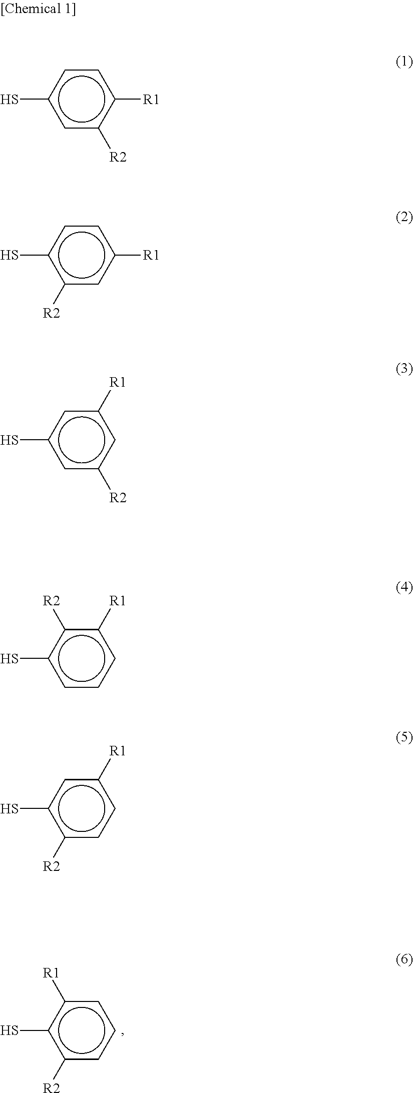
where SH denotes the thiol group, where R1 and R2 each independently denote any of a hydrogen atom, a methyl group, a methoxy group, an ethyl group and a propyl group, where at least one of R1 and R2 denotes any of a methyl group, an ethyl group and a propyl group.

7. The light-emitting element according to claim 1, wherein
the ligand contains at least one selected from the group consisting of compounds that are expressed by the following structural formulas (1) to (2): 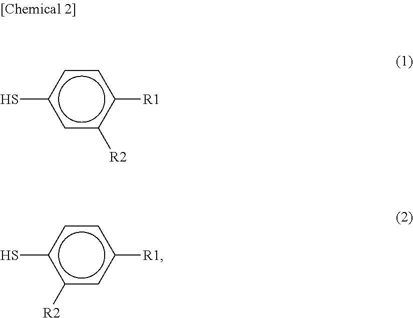
where SH denotes the thiol group, where R1 denotes any of a methyl group, an ethyl group and a propyl group, where R2 denotes any of a hydrogen atom, a methyl group, a methoxy group, an ethyl group and a propyl group.

8. The light-emitting element according to claim 1, wherein the ligand is para-toluenethiol (p-Toluenethiol).

9. The light-emitting element according to claim 1, wherein
the ligand contains at least one selected from the group consisting of compounds that are expressed by the following structural formulas (7) to (9): 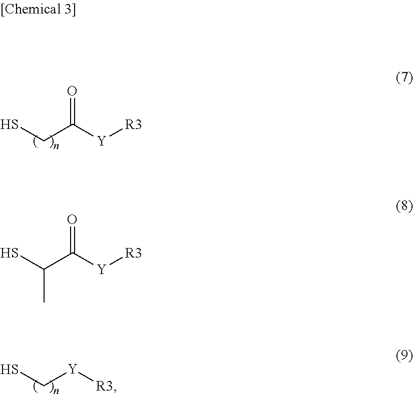
where SH denotes the thiol group, where Y denotes an oxygen atom or an imino group, where R3 denotes a substituted or non-substituted alkyl group having one or more and nine or less carbon atoms, where n denotes one or two.

10. The light-emitting element according to claim 1, wherein the ligand contains at least one selected from the group consisting of 3-mercaptopropionic acid methyl, 3-mercaptopropionic acid ethyl, 3-mercaptopropionic acid butyl, 3-mercaptopropionic acid isooctyl, 2-mercaptopropionic acid ethyl, 3-mercapto-N-nonylpropionamide, thioglycolic acid methyl, thioglycolic acid ethyl, thioglycolic acid 2-ethylhexyl and 2-(butylamino) ethanethiol.

11. The light-emitting element according to claim 1, wherein the nanoparticle has an average particle diameter of 1 to 5 nm inclusive.

12. The light-emitting element according to claim 1, wherein the metal oxide contains at least one selected from the group consisting of zinc oxide, titanium dioxide, tin dioxide, nickel oxide, zirconium dioxide, tungsten trioxide and tantalum pentoxide.

13. The light-emitting element according to claim 1, wherein the light-emitting layer includes a quantum dot configured to emit blue light.

14. A display device comprising the light-emitting element according to claim 1.

15. (canceled)

16. A method for producing a light-emitting element, comprising:
a reaction step of causing a metal-oxide precursor to react with a hydroxide ion within a first solution to generate a nanoparticle including a metal oxide;
a first addition step of generating, after the reaction step, a quantum dot including the nanoparticle and a ligand within a second solution in which a first alcohol and the ligand containing a thiol group are added to the nanoparticle; and
an application step of applying a third solution containing the quantum dot onto a substrate after the first addition step.

17. The method for producing the light-emitting element according to claim 16, further comprising a second addition step of further adding a second alcohol to the quantum dot after the first addition step.

18. The method for producing the light-emitting element according to claim 16, wherein
the metal-oxide precursor contains a metal ion and a negatively ionized acid, and
the hydroxide ion is contained in a hydroxide-ion precursor containing a positively ionized base.

19. The method for producing the light-emitting element according to claim 18, wherein
the negatively ionized acid is at least one selected from the group consisting of an acetate ion and a chloride ion, and
the positively ionized base contains at least one selected from the group consisting of a polyatomic ion that is expressed by the following structural formula (10), a lithium ion and a potassium ion: 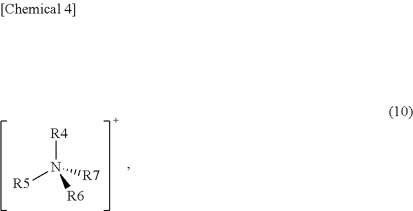
where R4 denotes a methyl group or an ethyl group, where R5, R6 and R7 each independently denote a hydrogen atom, a methyl group or an ethyl group.

20. The method for producing the light-emitting element according to claim 19, further comprising, between the reaction step and the first addition step, a first cleaning step of cleaning the first solution by using at least one selected from the group consisting of acetone, ethyl acetate, butyl acetate, hexane, octane, toluene and methanol.

21. The method for producing the light-emitting element according to claim 16, wherein
the ligand contains a compound having three or more and seven or less carbon atoms per molecule, and
the method further comprises, between the first addition step and the application step, a second cleaning step of cleaning the second solution by using at least one selected from the group consisting of hexane, octane and toluene.
